(19) United States
(12) Patent Application Publication
(10) Pub. No.: US 2012/0112345 A1
(43) Pub. Date: May 10, 2012

(54) HIGH BANDWIDTH SEMICONDUCTOR BALL GRID ARRAY PACKAGE

(75) Inventors: Kim J. Blackwell, Owego, NY (US); Frank D. Egitto, Binghamton, NY (US); Voya R. Markovich, Endwell, NY (US)

(73) Assignee: Endicott Interconnect Technologies, Inc., Endicott, NY (US)

(21) Appl. No.: 12/939,659

(22) Filed: Nov. 4, 2010

(51) Int. Cl. H01L 23/48; H01L 21/44

(52) U.S. Cl. 257/738; 438/613; 257/E23.011; 257/E23.079; 257/E21.476

(57) ABSTRACT

A high bandwidth semiconductor printed circuit board assembly (PCBA) providing a layer of dielectric substrate containing plated vias with an upper and lower surface plated with etched copper, mated with a second layer of etched copper plated dielectric containing plated vias that is placed on the top surface of the first layer. A third layer of etched copper plated dielectric containing plated vias may be placed on the bottom layer of etched copper foil. A base layer of etched copper plated thick dielectric containing plated vias is laminated simultaneously with the preceding layers to provide the high bandwidth digital and RF section of the assembly.

### FIELD OF THE INVENTION

The present invention relates to manufacturing and preparation of circuit boards and, more specifically, to a structure wherein the assembly contains asymmetric construction of a thick, high bandwidth dielectric layer disposed vertically relative to thin, dense packed digital circuitry dielectric layers.

### BACKGROUND OF THE INVENTION

The needs of the semiconductor marketplace continue to drive successively higher density into semiconductor packages. The high end of this market continues to have a need for an increasing number of signal, power, and ground die pads. A corresponding decrease in pad pitch is required to maintain reasonable die sizes. The combination of these two needs is affecting complex semiconductor packaging designs.

Traditionally, greater wiring densities have been achieved by reducing the dimensions of vias, lines, and spaces, increasing the number of wiring layers, and utilizing blind and buried vias. However, each of these approaches, for example, those related to drilling and plating of high aspect ratio vias, reduced conductance of narrow circuit lines, and increased cost of fabrication related to additional wiring layers possesses inherent limitations. One method of extending wiring density beyond the limits imposed by these approaches is a strategy that allows for metal-to-metal z-axis interconnection of sub-composites during lamination to form a composite structure.

Conductive joints can be formed during lamination using an electrically conductive adhesive. As a result, one is able to fabricate structures with vertically terminated vias of arbitrary depth. Replacement of conventional plated through holes with vertically-terminated vias opens up additional wiring channels on layers above and below the terminated vias and eliminates via stubs which cause reflective signal loss. More and more substrate designs require signal paths that can handle frequencies on the order of multi-gigahertz.

The packaging industry is also experiencing difficulty designing high-density packages for high bandwidth applications. Presently, the ball grid array (BGA) plastic package presents the optimum method for dense connections from a chip package to a printed wiring board. The array connection enables optimum use of both chip package and PCB surface area. However, the BGA pad or any large connector or even component pad becomes an electrical plane. This large inductive pad requires compensation with capacitance to provide both clean signals and clean power supply.

At bandwidths approaching 40 Gb/s, connectors such as ball grid, land grid, pin grid, column grids or SMT connectors require a pad as part of the chip package. However the cross sections for these packages limit the use of these connections for high bandwidth applications. The current cross sections can provide only thin dielectric layers between these pads and planes above them.

Future packages, especially System in Package (SiP), will have to combine thick dielectric layers or discrete non-metal areas for RF signals, with a thin dielectric layer containing dense wiring for digital signals. This package, as it is built currently, is a complete serial build beginning with a base layer. Semiconductor packaging companies generally have to build packages serially from the center out, starting with a core layer. This significantly limits package body size reduction. This method also limits off-module I/O density by limiting the use of array connections such as BGAs. In current technologies, the major RF sections of a module are laid out horizontally adjacent to the digital sections, in the width and/or length directions. The technologies in use today are additionally limited in the ability to laminate large numbers of layers due to manufacturing equipment limitations.

It is an object of the invention to add digital circuit build-up layers on top and/or bottom of a very high bandwidth substrate as an alternative to the current side-by-side packaging layout to improve overall packaging density.

A further object of the invention is directed to combining roll processing with panel processing and Z-interconnects between layers to enable the fabrication of the described package.

Another object of the invention is directed to using one and two layer, laser drilled, fully circuitized rolled materials fabricated on base dielectrics such as polyimide (Kapton), polyester (Mylar), PTFE (Teflon), liquid crystal polymer (LCP), and nano particle based dielectrics to provide base core layers.

Still another object of the invention is to utilize nano particle doped dielectric materials to allow custom capacitance within the dielectric layer.

Yet another object of the invention is to allow a thick high bandwidth layer to be fabricated in parallel with a thin, low cost, dense, digital wiring layer or layers, and laminated together as a sequential step in the manufacturing process, as a replacement for a totally sequential process currently being performed.

Another object of the invention is to allow a high bandwidth semiconductor package to be assembled in a non-symmetrical layered manufacturing process.

It would be advantageous to provide a cross section and fabrication method to allow for high density interconnects, such as ball grid arrays, to continue to be implemented for future applications.

### DISCUSSION OF RELATED ART

U.S. Pat. Nos. 7,414,299 and 7,432,593, by Quinlan, et al., granted Aug. 19, 2008 and Oct. 7, 2008, respectively, for SEMICONDUCTOR PACKAGE ASSEMBLY AND METHOD FOR ELECTRICALLY ISOLATING MODULES disclose a semiconductor package assembly and method for electrically isolating modules, having a capacitor within the semiconductor package assembly. The package assembly and method are suitable for electrically isolating modules according to IEEE 1394.

U.S. Pat. No. 6,949,992, by Sweeney, et al., granted Sep. 27, 2005 for a SYSTEM AND METHOD OF PROVIDING HIGHLY ISOLATED RADIO FREQUENCY INTERCONNECTIONS discloses a surface mount technology (SMT) apparatus for use in routing radio frequencies (RF) between cavities that require a high level of isolation on a single printed circuit board (PCB). The SMT is attached to the PCB over a stripline-ready trace which transitions to microstrip before and after the SMT stripline part to maintain consistent characteristic impedance.

U.S. Pat. No. 6,594,893, by Bailey, et al., granted Jul. 23, 2003 for METHOD OF MAKING SURFACE LAMINAR CIRCUIT BOARD discloses a surface laminar circuit board that includes an insulating layer and a signal ground conductive layer disposed on an upper surface of the insulating layer. The conductive layer has a hole formed therein. A photosensitive dielectric layer is disposed on an upper surface of the signal ground conductive layer. The dielectric layer has a photo micro-via formed therein and a signal trace is disposed on the photosensitive dielectric layer, and is electrically coupled with the signal ground conductive layer by way of the photo micro-via. A conductive pad is provided, which has a majority thereof within an area defined by an outer periphery of the hole. The conductive pad is electrically coupled with the signal trace. A surface mounted component is mounted on the conductive pad.

U.S. Pat. No. 5,177,324, by Carr, et al., granted Jan. 5, 1993 for IN SITU RF SHIELD FOR PRINTED CIRCUIT BOARD discloses a printed circuit board providing RF shielding. An electrically insulating material serves as a substrate with two opposed sides. At least one side of the substrate has an electrically conductive layer formed in a pattern that defines a printed circuit. An insulating dielectric layer covers at least a portion of the printed circuitry, leaving at least one portion of the circuitry exposed. A radio frequency shielding layer is formed by depositing an electrically conductive polymer on at least a portion of the insulating dielectric layer. The RF shielding layer also lies over a portion of the exposed electrical circuitry, providing electrical connection to the electrically conductive layer. The RF shielding layer is formed from a silver filled polymer thick film ink.

U.S. Pat. No. 5,550,713, by Pressler, et al., granted Aug. 27, 1996 for ELECTROMAGNETIC SHIELDING ASSEMBLY FOR PRINTED CIRCUIT BOARD discloses a shielding assembly for a PC board having ground trace segments on a surface of the board. The shielding assembly includes a cover, a shielding assembly, a sealing gasket and a fastener. The cover includes an integrally molded base portion and a fencing portion extending outwardly from a surface of the base portion. The fencing includes peripheral edges configured to overlie the ground trace segments. The sealing gasket is disposed between the fencing and the ground trace segments. The fastener mechanically couples the cover to the PC board surface.

U.S. Pat. No. 7,358,603, by Li, et al., granted Apr. 15, 2008 for HIGH DENSITY ELECTRONIC PACKAGES discloses a high-density electrical package utilizing an array of high performance demountable electrical contacts such as UEC, T-Spring, F-Spring and their equivalent contained in a carrier in the form of an interposer between one or more components and a substrate. The carrier is made of a thermally conductive metal or contains thermally conductive metal to provide heat-spreading or dissipation in addition to the retention and alignment of the electrical contacts. The interposer is used for chip attach for a single chip or a stack of chips in the package. The interposer provides electrical connections through individual electrical contact to another chip or to the substrate of the package. It also provides heat spreading or dissipation to the chips connected thermally to a particular interposer. The interposer can be connected thermally to an external heat spreader when necessary.

### SUMMARY OF THE INVENTION

According to the present invention, there is provided a method and structure for a very high bandwidth semiconductor package that provides for the combined need for high density package interconnects and digital along with radio frequency application bandwidths approaching 40 Gbps in a single, vertically integrated package. A method and structure are provided for manufacturing a layer of dielectric substrate containing plated vias with an upper and lower surface with plated and etched copper, mated with a second layer of etched copper plated dielectric containing plated vias that is placed on the top surface of the first layer. A third layer of dielectric containing plated vias is placed on the bottom layer of etched copper foil. A base layer of etched copper plated thick dielectric containing plated vias, laminated together with any number of the previous layers, provides the high bandwidth digital and RF section of the package.

### BRIEF DESCRIPTION OF THE DRAWINGS

These and other features and advantages of this invention will be more readily understood from the following detailed description of the various aspects of the invention taken in conjunction with the accompanying drawings in which:

FIG. 1 shows a sectional view illustrative of prior art;

FIG. 2 shows a sectional view of single layer of dielectric prior to lamination;

FIG. 3 shows a sectional view of the laminating structure of the digital wiring layer members to form a printed wiring board according to one embodiment of the invention; and

FIG. 4 shows a sectional view of the Z direction layering of the radio frequency, high bandwidth digital section and that of the dense digital circuitry required for interconnections between layers.

It is noted that the drawings of the invention are not to scale. The drawings are merely schematic representations, not intended to portray specific parameters of the invention. The drawings are intended to depict only typical embodiments of the invention, and therefore should not be considered as limiting the scope of the invention. For the sake of clarity and brevity, like elements and components of each embodiment will bear the same designations throughout the description.

### DESCRIPTION OF THE PREFERRED EMBODIMENT

In the invention, a method and structure are provided for use in electronic packages in which a high bandwidth semiconductor layer is used to create a vertically integrated high bandwidth semiconductor package.

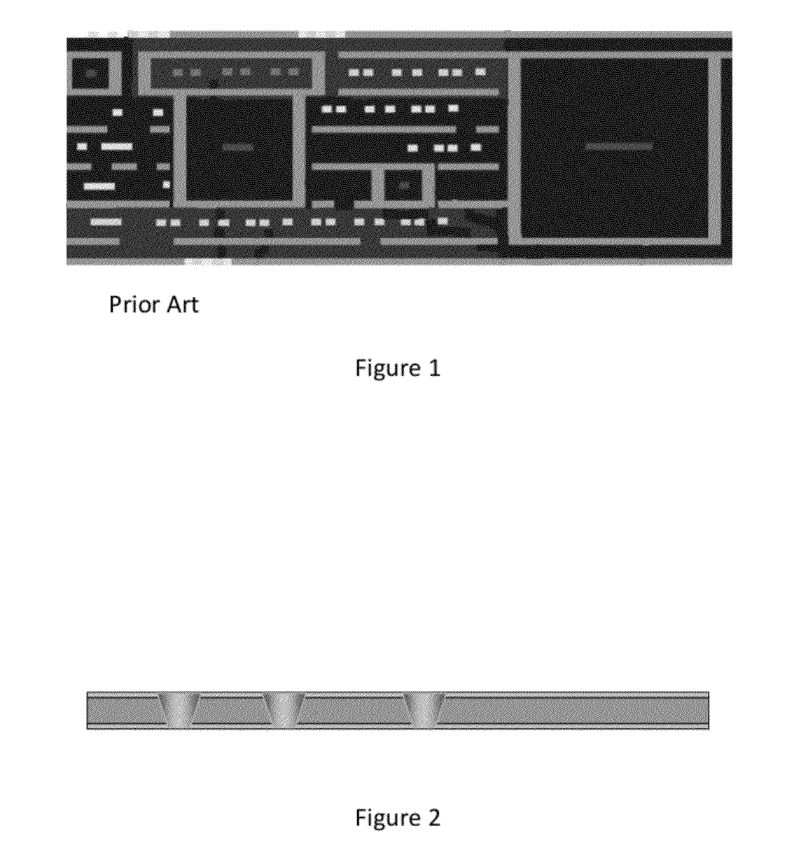

Referring now to FIG. 1, there is shown a sectional view of a circuit board 10 that is illustrative of the prior art. As shown, large RF sections 12 of circuit board 10 are positioned adjacent to digital signal sections 14 on an x-axis plane. Ground and power planes 16 border the RF sections 12 to isolate the surrounding digital sections 14 from interference. This use of large features for RF sections 12 is required for controlling impedance. To include in the circuit board 10 layout both the RF sections 12 and digital signal sections 14 utilizing the x-axis plane required a larger area footprint than the present invention requires. The prior art ignores circuit board designers' requirements for high bandwidth capabilities and a production requirement for smaller circuit board footprint.

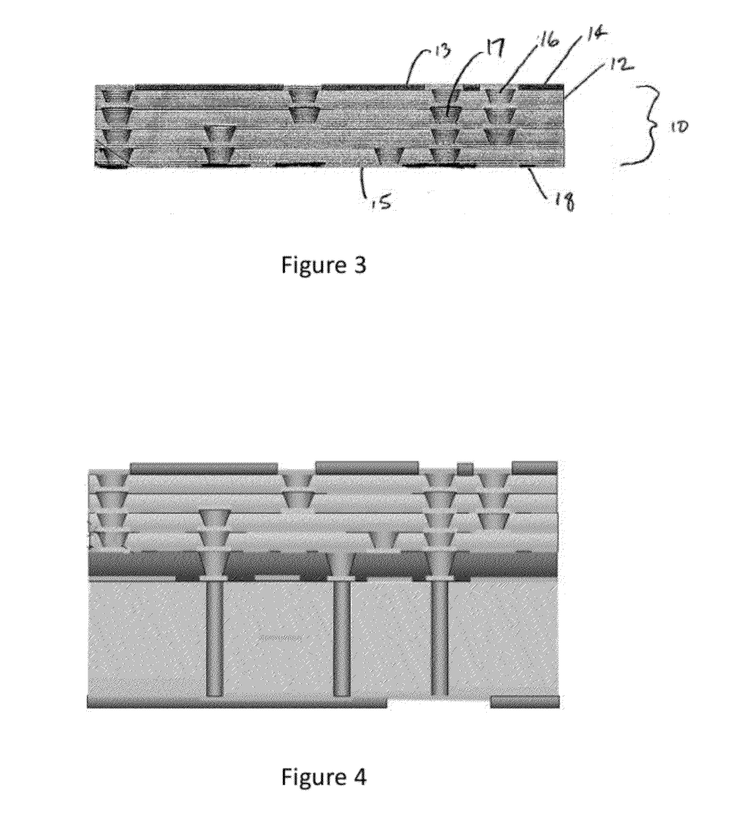

Referring now to FIG. 2, a single layer of dielectric substrate 20 is shown. Dielectric substrate 20 can be made from any conventional dielectric material, such as FR4 (a glass reinforced epoxy), polyimide, polytetrafluoroethylene or other suitable well-known dielectric material. As shown, dielectric substrate 20 includes vias 26 that are plated 27 with electrically conductive material such as copper, used to create Z-interconnects 37 (FIG. 3). Copper layers 22 and 24 are typically created in thicknesses ranging from one-third ounce copper (12 μm thick), to one ounce copper (35 μm thick) to two ounce copper (70 μm thick). However, other thicknesses of copper layers can be used. Plated metal layer 27 is shown prior to etching circuit features.

Referring now to FIG. 3, a printed wiring board assembly 30 represents the high density digital interconnects section of the invention. PWB 30 contains individual layers of dielectric 20 that include circuit traces 34 and 38. Copper layers 22 and 24 are preferably patterned or etched to form circuit traces 34 and 38, respectively. Any conventional patterning process can be used, such as by using a photoresist, exposing, developing and etching the exposed areas and then stripping the photoresist.

In addition to the above, it is also possible (and in some instances preferred) to use a semi-additive plating technique as a patterning process. In one example, a relatively thin (1000 Angstroms to 6000 Angstroms) layer of metal, typically copper, would be deposited onto the surface of the substrate to be plated. This metal “seed layer” is commonly applied using sputter deposition and/or a chemical seed and electro-less plating processes. Photoresist is then applied, exposed, and developed to generate a reverse mask; that is, the mask serves to precisely expose those areas of the substrate that will eventually have the metal traces thereon. Additional metal is then plated onto the substrate in the unmasked areas. The thickness of the metal is less than the thickness of the photoresist mask. Copper is commonly used for the metal, and subsequent plating steps can be employed to deposit other metals (e.g., nickel and gold), onto the surface of the copper. After plating, the photoresist is removed, exposing the thin layer of metal on the surface of the substrate. A quick etching step, or flash etch, is used to remove this thin seed layer, isolating the individual circuit features. Since the seed layer is much thinner than the plated features, the latter are not significantly distorted by the flash etch.

Z-interconnects 37 are created by screening, stenciling, flood coating, doctor blading, immersing or injecting these vias 26 with conductive adhesive 32. Various types of conductive material may be used. A preferred conductive polymer material is a conductive epoxy sold by National Starch and Chemical Company under the trademark Ablebond 8175, formerly sold by Ablestik Corporation. Ablebond 8175 is a silver filled thermosetting epoxy. Another example of a conductive paste usable herein is sold under the trade name “DA-5915” by Engineered Materials Systems of Delaware, Ohio. DA-5915 includes about 88% by weight silver flakes and about 12% by weight of an anhydride epoxide as the organic binder. The Z-interconnects 37 allow signals to be routed from the lower surface 35 of PWB 30 to the upper surface 33 thereof and vice-versa according to the needs of the designer. The terms lower surface and upper surface are meant to convey generic location conditions, and not to imply a mono-directional capability of the present invention.

Moreover FIG. 3 shows a plurality of dielectric substrates 20, 20a, 20b, and 20c laminated together. Conductive adhesive 32 creates an electrical connection between vias 26 and 26′ disposed in dielectric substrates 20 and 20a, respectively. Dielectric substrates 20, 20a, 20b, and 20c may include, for example, a power plane, signal plane, or ground plane. These thin dielectric layers enable very dense circuitry needed to wire digital applications.

Another means of providing electrical connection between vias 26 and 26′ disposed in dielectric substrates 20 and 20a, respectively, includes use of metal surface finishes transient liquid phase joining (e.g., tin). Still another means of providing electrical connection includes use of a separate joining core between dielectric substrates 20 and 20a. The core contains through holes at positions of vias 26 and 26′, the through holes being filled with conductive adhesive, as is shown connecting the high density digital interconnects section 30 to the high bandwidth semiconductor package 40 in FIG. 4.

Referring now to FIG. 4, the high bandwidth semiconductor package 40 contains printed wiring board assembly 30 as the high density digital interconnect section and a thick dielectric layer 41 that is the high bandwidth RF section 42. The thick (250 μm) dielectric layer 41 can be low K, low Loss or high K, and provides desired electrical performance for both RF and high bandwidth digital applications. The use of thick dielectric layer 41 is required to properly control impedances within the high bandwidth RF section 42.

A metal layer 48 between the thick dielectric high bandwidth RF section 42 and printed wiring board assembly 30 is either a ground or power plane to allow for electrical isolation of the two sections. Drilled and plated through holes 44 connect the BGA pad 45 on the connecting pad plane 46 to the printed wiring board assembly 30 to route signals (not shown) to their respective destinations. A solder mask 47 provides a protective coating to the exposed exterior portions of high bandwidth semiconductor package 40.

It is also possible to join dielectric layers 20, 20a, 20b, 20c, and the high bandwidth RF section 42 in a single lamination step. It is further possible to join combinations of dielectric layers 20, 20a, 20b, 20c, for example layers 20 with 20a, and/or 20b with 20c, prior to or joining with the high bandwidth RF section 42.

Thus, the inventive method for forming a high bandwidth semiconductor package substrate includes the steps of:

Providing a layer of dielectric substrate containing plated vias with an upper and lower surface plated with etched copper, mated with a second layer of etched copper plated dielectric containing plated vias that is placed on the top surface of the first layer. A third layer of dielectric containing plated vias is placed on the bottom layer of etched copper foil. A base layer of etched copper plated thick dielectric containing plated vias is laminated simultaneously with the previous layers to provide the high bandwidth digital and RF section of the package.

Since other modifications and changes to the high bandwidth semiconductor package effected as such will be apparent to those skilled in the art, the invention is not considered limited to the description above for purposes of disclosure, and covers all changes and modifications which do not constitute departures from the true spirit and scope of this invention.

Having thus described the invention, what is desired to be protected by Letters Patent is presented in the subsequently appended claims.

What is claimed is:

1. In a high bandwidth semiconductor printed circuit board assembly (PCBA) for use in electronic packages comprising a first layer of dielectric substrate having an upper surface and a lower surface and containing plated vias; a first etched layer of copper foil disposed on said upper surface of said first layer of dielectric substrate; a second etched layer of copper foil disposed on said lower surface of said first layer of dielectric substrate, forming a first subassembly; and a second layer of dielectric substrate having an upper surface and a lower surface and containing plated vias; a third etched layer of copper foil disposed on said upper surface of said second layer of dielectric substrate; a fourth etched layer of copper foil disposed on said lower surface of said second layer of dielectric substrate, forming a second subassembly; wherein said first and said second subassemblies are laminated together, the improvement comprising:
a) a base layer of thick dielectric substrate having an upper surface and a lower surface and containing plated vias;
b) a top layer of etched copper foil disposed on said upper surface of said thick dielectric substrate layer;
c) a bottom layer of etched copper foil disposed on said lower surface of said thick dielectric substrate layer; and
d) wherein said laminated subassemblies are disposed on said top layer of etched copper foil disposed on said upper surface of said base layer of thick dielectric substrate.

2. The high bandwidth semiconductor PCBA for use in electronic packages as in claim 1, wherein all of said layers are laminated together.

3. The high bandwidth semiconductor PCBA for use in electronic packages as in claim 1, wherein all said layers of dielectric substrate comprise at least one material taken from the group: polyimide (Kapton), polyester (Mylar), PTFE (Teflon), liquid crystal polymer (LCP), and nano particle based dielectrics.

4. The high bandwidth semiconductor PCBA for use in electronic packages as in claim 1, wherein said base layer of thick dielectric comprises material having at least one property from the group: low K, low loss and high K.

5. The high bandwidth semiconductor PCBA for use in electronic packages as in claim 1, wherein said bottom layer of etched copper foil contains a connecting pad plane.

6. The high bandwidth semiconductor PCBA for use in electronic packages as in claim 5, wherein said connecting pad plane comprises BGA contact points.

7. The high bandwidth semiconductor PCBA for use in electronic packages as in claim 1, wherein said top layer of etched copper foil is used for one of the group: ground and power.

8. In a high bandwidth semiconductor printed circuit board assembly (PCBA) for use in electronic packages comprising a first layer of dielectric substrate having an upper surface and a lower surface and containing plated vias; a first etched layer of copper foil disposed on said upper surface of said first layer of dielectric substrate; a second etched layer of copper foil disposed on said lower surface of said first layer of dielectric substrate, forming a first subassembly, the improvement comprising:
a) a base layer of thick dielectric substrate having an upper surface and a lower surface and containing plated vias;
b) a top layer of etched copper foil disposed on said upper surface of said thick dielectric substrate layer;
c) a bottom layer of etched copper foil disposed on said lower surface of said thick dielectric substrate layer; and
d) wherein said laminated subassemblies are disposed on said top layer of etched copper foil disposed on said upper surface of said base layer of thick dielectric substrate.

9. The high bandwidth semiconductor PCBA for use in electronic packages as in claim 8, wherein all of said layers are laminated together.

10. The high bandwidth semiconductor PCBA for use in electronic packages as in claim 8, wherein all said layers of dielectric substrate comprise at least one material taken from the group: polyimide (Kapton), polyester (Mylar), PTFE (Teflon), liquid crystal polymer (LCP), and nano particle based dielectrics.

11. The high bandwidth semiconductor PCBA for use in electronic packages as in claim 8, wherein said base layer of thick dielectric comprises material having at least one property from the group: low K, low loss and high K.

12. The high bandwidth semiconductor PCBA for use in electronic packages as in claim 8, wherein said bottom layer of etched copper foil contains a connecting pad plane.

13. The high bandwidth semiconductor PCBA for use in electronic packages as in claim 12, wherein said connecting pad plane comprises BGA contact points.

14. The high bandwidth semiconductor PCBA for use in electronic packages as in claim 8, wherein said top layer of etched copper foil is used for one of the group: ground and power.

15. A method of forming a high bandwidth semiconductor PCBA, the steps comprising:
a) providing a base layer of thick dielectric substrate having an upper surface and a lower surface and containing plated vias;
b) disposing a first etched copper foil layer on said upper surface of said base layer of thick dielectric substrate;
c) disposing a second etched copper foil layer on said lower surface of said base layer of thick dielectric substrate, forming a base subassembly;
d) providing a second dielectric layer having an upper surface and a lower surface and containing plated vias and having a third etched copper foil layer and a fourth etched copper foil layer disposed on said upper and said lower surfaces of said second dielectric layer, respectively, forming a high density digital interconnect subassembly;
e) disposing said high density digital interconnect subassembly on said first etched copper foil layer of said base layer of thick dielectric substrate; and
f) laminating all of said layers together jointly.

16. The method of forming a high bandwidth semiconductor PCBA as in claim 15, wherein said base layer of thick dielectric substrate comprises at least one material taken from the group: polyimide (Kapton), polyester (Mylar), PTFE (Teflon), liquid crystal polymer (LCP), and nano particle based dielectrics.

17. The method of forming a high bandwidth semiconductor PCBA as in claim 16, wherein said base layer of thick dielectric substrate comprises material having at least one property from the group: low K, low loss and high K.

18. The method of forming a high bandwidth semiconductor PCBA as in claim 15, wherein said second dielectric layer comprises at least one material taken from the group: polyimide (Kapton), polyester (Mylar), PTFE (Teflon), liquid crystal polymer (LCP), and nano particle based dielectrics.
